(19) United States
(12) Patent Application Publication
(10) Pub. No.: US 2007/0096787 A1
(43) Pub. Date: May 3, 2007

(54) Method for improving the timing resolution of DLL controlled delay lines

(75) Inventor: John D. Heightley, Colorado Springs, CO (US)

Correspondence Address: HOGAN & HARTSON LLP, ONE TABOR CENTER, SUITE 1500, 1200 SEVENTEENTH ST, DENVER, CO, 80202, US

(73) Assignees: United Memories, Inc.; Sony Corporation

(21) Appl. No.: 11/265,962

(22) Filed: Nov. 3, 2005

(51) Int. Cl. H03H 11/26

(52) U.S. Cl. 327/276

(57) ABSTRACT

The timing resolution of a DLL based delay line can be achieved by making the number of delay stages in the master voltage-controlled delay line variable. By adjusting both the tap selected on a slave voltage-controlled delay line as well as the number of stages of delay in the master voltage-controlled delay line, the timing resolution can be improved by at least a factor of two when compared to previous delay line circuits using a fixed length master voltage-controlled delay line.

### FIELD OF THE INVENTION

The present invention is related to an apparatus and method for finely controlling the timing resolution of a delay line, and, more particularly, to an embodiment and method thereof using a master voltage-controlled delay line in a delay locked loop, and at least one slave voltage-controlled delay line.

### BACKGROUND OF THE INVENTION

A delay locked loop (DLL) can be used to achieve precisely controlled individual delay-stage delays by forcing a DLL to lock with the delay through the master delay line, equal to a single clock period of delay. For a given number of stages of delay, N, the delay per stage is equal to the precisely controlled clock period divided by N. If taps to the output are included at each stage of the delay line, an output signal can be created that has a variable delay with respect to the input to the delay line. Choosing a specific tap selects the desired delay. The resolution between delays is equal to the delay through a single stage of the delay line.

If a voltage controlled delay line is used as the master delay line in the DLL, it is possible to use the control voltage established by the DLL when it locks with one clock period of delay to control the delay through one or more “slave” delay lines. By using delay stages in the slave delay line that are substantially identical to the N stages in the master delay line and using the control voltage established by the DLL, the delay per stage in the slave delay line is also equal to one clock period divided by N. By including taps at each stage of the slave delay line, an output signal can be created that can be adjusted in delay with respect to the input signal to the slave delay line. The input to the slave delay line does not have to have any specific relationship to the input to the master delay line since the master delay line is only used to establish the delay per stage and the control voltage established when the DLL locks with a delay of one clock period. In this way, precisely controlled delays for multiple signals can be achieved by using multiple tapped slave delay lines.

However, with only the taps of the slave delay line selectable and the master delay line fixed, the timing resolution is limited by the fixed number of stages in the master DLL delay line, since the resolution is equal to the clock period divided by the number of stages.

What is desired, therefore, is a circuit and method for improving the timing resolution of a delay line beyond that of the prior art DLL circuit and technique using a fixed length DLL delay line as described above.

### SUMMARY OF THE INVENTION

According to an embodiment of the present invention, an improvement on the timing resolution of a prior art DLL based delay line can be achieved, in part, by making the number of delay stages in the master DLL delay line variable. By adjusting both the tap selected on a slave voltage-controlled delay line as well as the number of stages of delay in the master DLL voltage-controlled delay line, the timing resolution can be improved by a factor of two in the worst case and by much more in most cases when compared to previous delay line circuits using a fixed length master voltage-controlled delay line.

According to an embodiment of the present invention, a delay line circuit includes a master voltage-controlled delay line including a selectable number of unit delay stages in a delay locked loop to establish unit delays and associated control voltages, and a slave voltage-controlled delay line slaved to the master voltage-controlled delay line also having a selectable number of unit delay stages in the slave delay path. The delay line circuit further includes a control block for providing control voltages to both the master voltage-controlled delay line and the slave voltage-controlled delay line. If desired, the delay line circuit can include one or more additional voltage-controlled slave delay lines slaved to the master voltage-controlled delay line. To assure the maximum precision in adjusting the timing resolution, the delay line circuit uses substantially identical unit delay stages in both the slave voltage-controlled delay line and in the master voltage-controlled delay line. For flexibility in a wide range of applications, both the length of the master voltage-controlled delay line and the number of unit delays in the slave voltage-controlled delay line can be electrically adjusted. In a particular embodiment of the present invention the master voltage-controlled delay line includes a fixed length portion and a selectable variable length portion, wherein the fixed length portion includes fifteen unit delay stages and wherein the variable length portion includes a maximum of eight delay stages. The master voltage-controlled delay line further includes multiplexing circuitry for receiving length control signals. The slave voltage-controlled delay line further includes multiplexing circuitry having an input for receiving tap select signals and an output for providing an output tap signal.

The foregoing and other features, utilities and advantages of the invention will be apparent from the following more particular description of an embodiment of the invention as illustrated in the accompanying drawings.

### BRIEF DESCRIPTION OF THE DRAWINGS

FIG. 1 is a detailed block diagram of delay line circuit according to an embodiment of the present invention including a master voltage-controlled delay line in a DLL, and two slave voltage-controlled delay lines, wherein each of the slave voltage-controlled delay lines have improved timing resolution;

FIG. 2 is a schematic diagram of a unit delay circuit including multiplexing circuitry, that is used in the slave voltage-controlled delay lines and the extension voltage-controlled delay line of FIG. 1;

FIG. 3 is a schematic diagram of a unit delay circuit that is used in the fixed-length voltage-controlled delay line of FIG. 1;

FIG. 4 is an example graph showing the possible slave delays for all combinations of the total number of stages in the master delay line and the number of stages in the slave between the input and the selected tap according to an embodiment of the present invention, wherein the fixed-length voltage-controlled delay line has fifteen stages, the extension voltage-controlled delay line has between one and eight stages, the slave voltage-controlled delay line has between one and sixteen stages;

FIG. 5 is a graph showing the difference in delay between two successive delays of the graph in FIG. 4, and compared to the timing resolution provided by a prior art fixed-length master voltage-controlled delay line with twenty-three delay stages; and

FIG. 6 is a table that shows the actual length and tap combinations with their associated delays and differences between successive delays according to an embodiment of the present invention.

### DETAILED DESCRIPTION

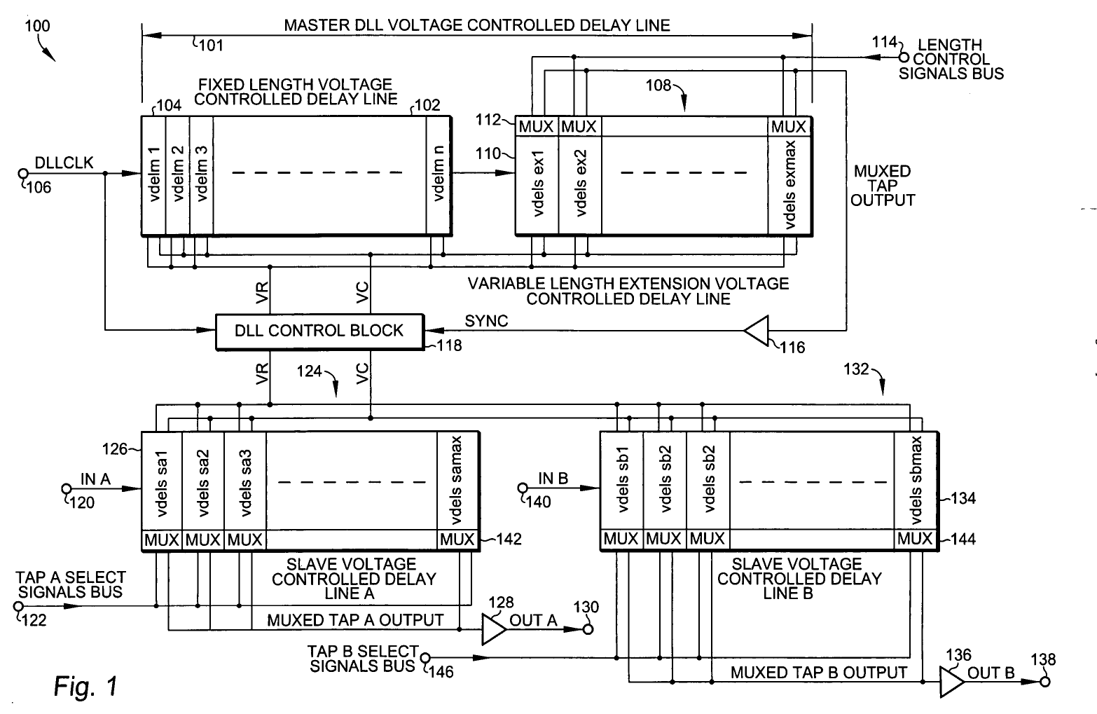

Referring now to FIG. 1, a schematic diagram of a delay line circuit 100 is shown including a master voltage-controlled delay line 101 having a fixed length portion 102 and an electrically selectable variable length extension portion 108. The fixed portion 102 of the master voltage-controlled delay line includes a number of unit delay stages 104 labeled “VDELM 1” through “VDELM N”. The fixed length portion 102 of the master voltage-controlled delay line (also known as and labeled “FIXED LENGTH VOLTAGE CONTROLLED DELAY LINE” in FIG. 1) includes an input node 106 for receiving the DLLCLK clock signal, which is the input reference clock signal. The output of the fixed length portion 102 of the master voltage-controlled delay line is coupled to the input node of the electrically selectable variable length portion 108. The variable portion 108 (also known as and labeled “VARIABLE LENGTH EXTENSION VOLTAGE CONTROLLED DELAY LINE” in FIG. 1) of the master voltage-controlled delay line 101 includes a selectable number of unit delay stages 110 labeled “VDELS EX1” through “VDELS EXMAX”. The variable portion 108 also includes multiplexing circuitry 112 for receiving the length control signals at bus 114, for selecting the exact number of unit delay stages 110 that are to be activated and thus the number of unit delay stages that are to be bypassed, i.e. the total length of the delay in the delay line extension 108. The output of the variable portion 108 of the master voltage-controlled delay line 101 is provided by the multiplexing circuitry 112 and is labeled “MUXED TAP OUTPUT” in FIG. 1, and is coupled to the input of buffer stage 116. The output of buffer stage 116 is labeled “SYNC”, which is received by the DLL control block 118, along with the DLLCLK input clock signal. The specific circuitry of the DLL control block 118 for a DLL using voltage-controlled delay lines is well known to those skilled in the art and typically includes at least a phase detector to compare a reference clock with a delayed version of the reference clock and to generate a control signal indicating whether the delay of the delayed clock should be increased or decreased, a charge pump and charge integrator that adjusts the control voltages in response to the phase detector signal, and circuitry to initialize and reset the control voltages. The DLL control block 118 provides VR and VC analog control voltages, which are used to modulate the delay of the unit delay stages of all of the voltage-controlled delay lines in delay line circuit 100. The DLL control block 118 adjusts the delay in the master voltage-controlled delay line 101 until the SYNC and DLLCLK signals are in phase and the delay is equal to one clock period.

Still referring to FIG. 1, a schematic diagram of a delay line circuit 100 is shown including two slave voltage-controlled delay lines 124 and 132 each having a variable delay length labeled “SLAVE VOLTAGE CONTROLLED DELAY LINE A” and “SLAVE VOLTAGE CONTROLLED DELAY LINE B”. Each slave voltage-controlled delay line includes a number of unit delay stages. In slave delay line 124, the unit delay stages 126 are labeled “VDELS SA1” through “VDELS SAMAX”. In slave delay line 132, the unit delay stages 134 are labeled “VDELS SB1” through “VDELS SBMAX”. Slave voltage-controlled delay line 124 includes an input node 120 for receiving the “IN A” clock signal, which is the input reference clock signal for that delay line. Slave voltage-controlled delay line 132 includes an input node 140 for receiving the “IN B” clock signal, which is the input reference clock signal for that delay line. Slave delay lines 124 and 132 each also include multiplexing circuitry 142 and 144 for the receiving the tap control signals. The “TAP A SELECT SIGNALS BUS” is received at bus 122, for selecting the exact number of unit delay stages 126, and the “TAP B SELECT SIGNALS BUS” is received at bus 146, for selecting the exact number of unit delay stages 134. The outputs of the slave voltage-controlled delay lines 124 and 132 are provided by the multiplexing circuitry 142 and 144. The outputs are labeled “MUXED TAP A OUTPUT” and “MUXED TAP B OUTPUT”, and are respectively couple to the input of buffer stages 128 and 136. The outputs of buffer stages 128 and 136 are respectively labeled “OUT A” and “OUT B”, at respective output nodes 130 and 138. Nodes 130 and 138 thus represent the delayed output clock signals for the two slave delay lines with respect to their respective input reference clock signals, the delays of which are finely adjusted as is explained in greater detail below.

The fixed-length delay line 102 in series with the extension delay line 108 determines the delay in the DLL loop. For given values of VR and VC, the delay through the individual delay stages of both of these delay lines and the slave delay lines are equal since the delay portion of the unit stages in all of the delay lines shown in FIG. 1 are substantially identical (except for multiplexing circuitry as is described in further detail below) and all of the unit delay stages share the same control voltages. Control voltages VR and VC are initialized at their extremes so as to minimize the initial delay through each stage. The minimum initial delay per stage is defined as “min”.

If the minimum DLLCLK period of interest is “tck” and the delay of the buffer amplifier is “buf”, then the maximum number of stages allowed in the fixed-length line plus the extension line is given by:
Max stages=(tck−buf)/min. [1]

This is because the maximum allowable delay between DLLCLK and SYNC is ideally less than or equal to one clock period when the DLL is initialized, to achieve the minimum possible delay per stage for a given clock frequency.

If the length control signals select tap L (1≦L≦exmax), then the delay per stage when the DLL is locked is (tck−buf)/(n+L) where “n” is the number of stages in the fixed-length delay line.

The purpose of the DLL master delay line 101 is to establish this fixed delay per stage and the associated values of VR and VC. The clock period is constrained to be between the minimum “tck” defined above and the maximum delay that can be achieved through the delay line with the maximum number of stages as defined above. This maximum clock period is on the order of five times “tck”.

The two slave delays have the same delay per stage as that established by the DLL as described above. The tap select signals at busses 122 and 146 determine how many stages of the slave delay lines are in the path between “IN A” or “IN B” and “OUT A” or “OUT B”, respectively. So, by using a DLL to establish accurate incremental delays that are only dependent on the clock frequency and are independent of power, temperature, or process variations, accurate positioning of the outputs of the slave delay lines with respect to the inputs can be maintained.

It is important to note that in the present invention, it is possible to adjust both the length of the master delay line in the DLL loop and the tap selection on the slave delay lines to achieve a higher timing precision than can be achieved by only selecting the output tap on the slave delay line.

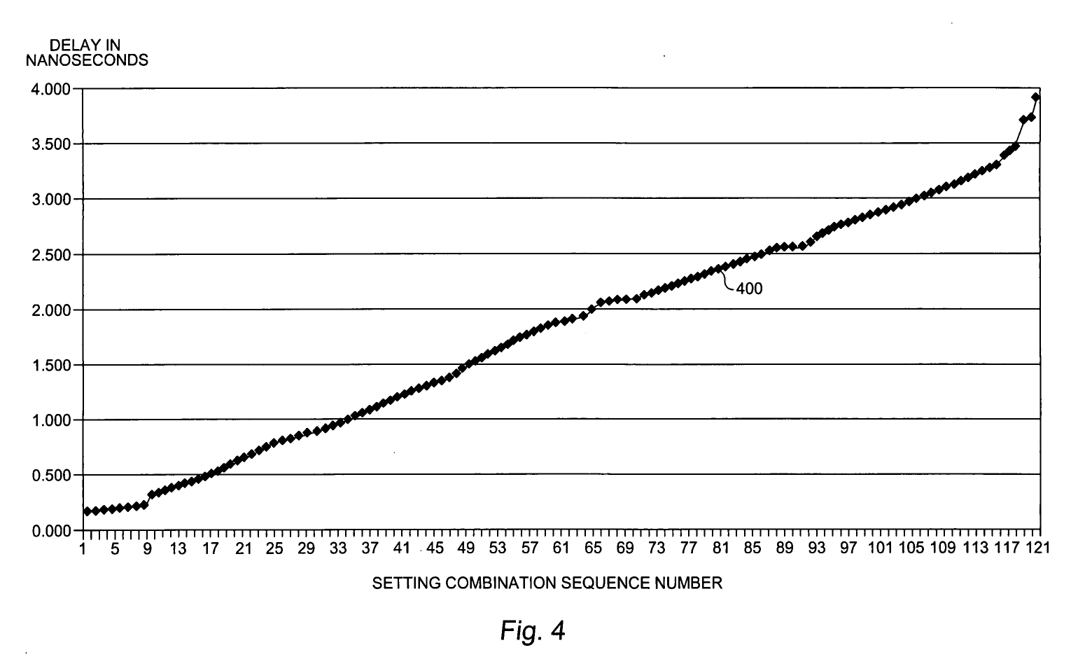

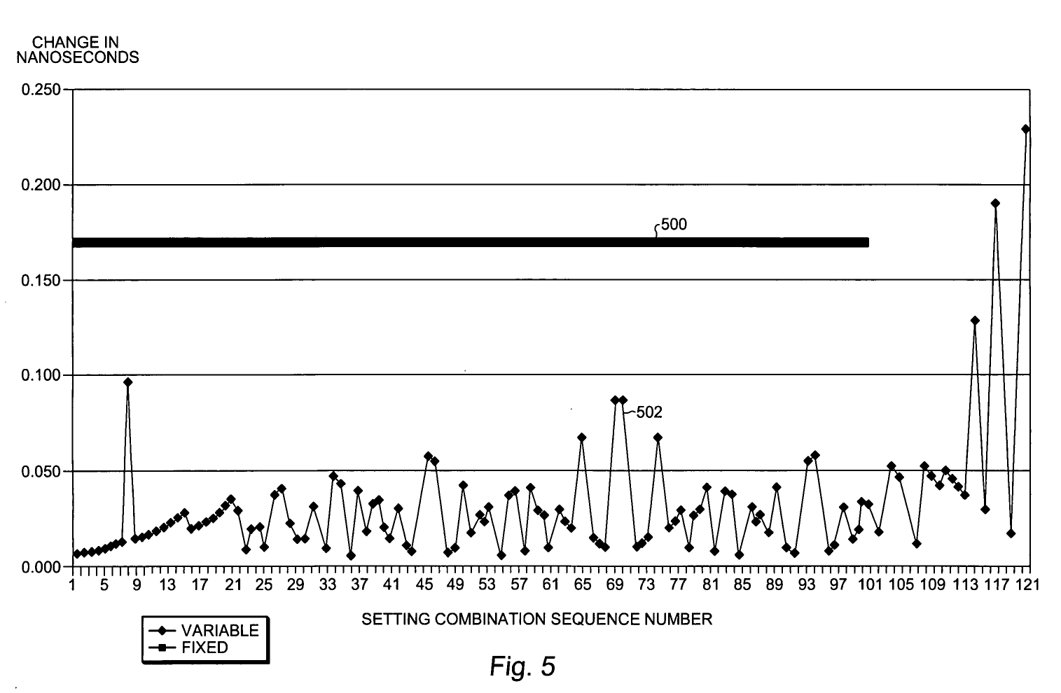

The specific delay between input and output of the slave for a length setting of “L” and a slave tap setting of “S”, is given by:
Delay=buf+S*(tck−buf)/(n+L). [2]
The graphs of FIGS. 4 and 5, explained in greater detail below, are generated from equation [2] for the case where “n” is equal to fifteen, 1≦L≦8, and 1≦S≦16. For greater accuracy, it is desirable to take into account and compensate for the buffer delay (produced by buffers 128 and 136) at the output of the slave delay lines in associated circuits utilizing the precisely controlled delay.

In FIG. 1, the DLL control circuitry 118 is essentially the same as is described in U.S. patent application Ser. No. 10/776,366, which has been incorporated by reference.

To illustrate the benefit of having the dual control of the slave delay, if the DLLCLK clock signal has a period of four nanoseconds, and the buffer delay is 0.1 ns, then the delay per stage with fifteen stages in the fixed-length delay line and eight stages in the extension delay line is 170 picoseconds. If the extension delay line is selected to be a single stage long by selecting the first tap, then total number of stages in the DLL locking loop is sixteen and the stage delay is 243 picoseconds. The change of 73 picoseconds is 43% of the minimum change possible if the fixed-length delay line has fifteen stages and the extension delay line is fixed at eight stages as it would be in the prior art. By selecting a smaller change in the length of the extension, even finer resolution is possible.

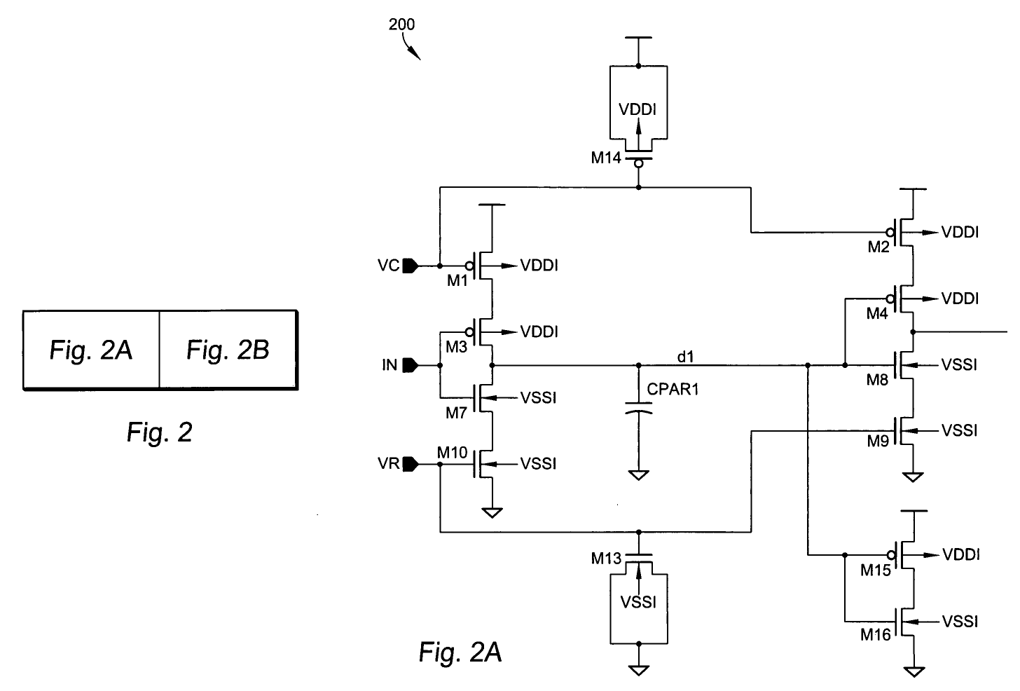

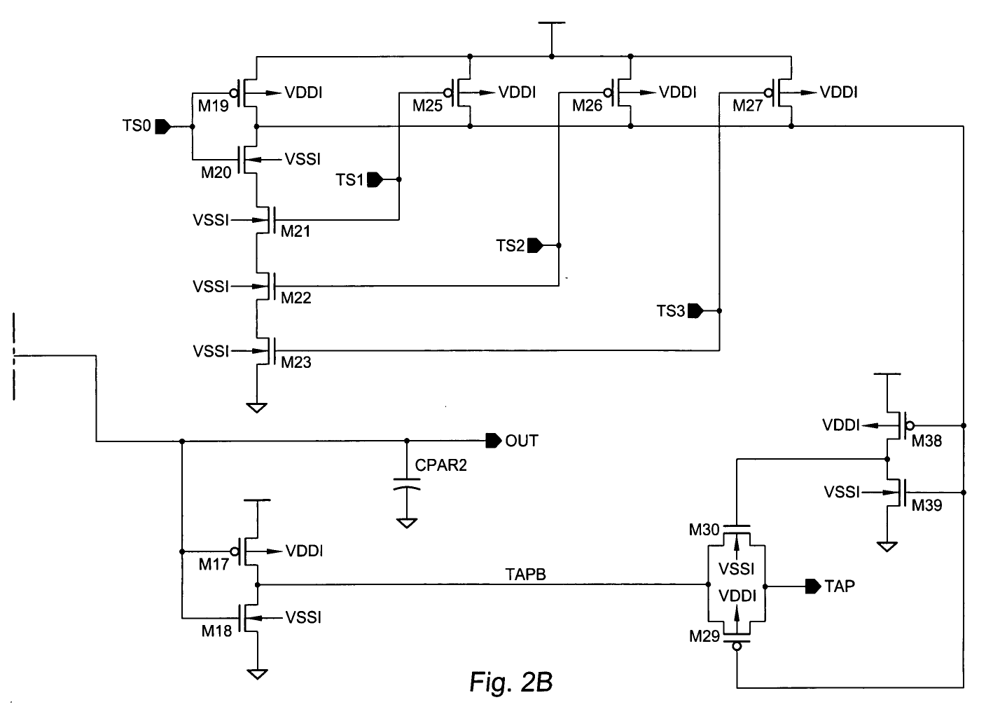

Referring now to FIG. 2, a transistor-level schematic is shown of a delay stage 200, designated “VDELS” in FIG. 1, that is used to implement the slave and extension delay lines. The delay stage circuit 200 includes the circuitry required to multiplex the output of the individual delay stage with the other delay stages in the same delay line onto a single output node.

The unit delay portion of delay stage 200 includes transistors M1, M3, M7, and M10 and M2, M4, M8, and M9 and their respective load capacitances, Cpar1 and Cpar2, on nodes D1 and OUT respectively. The propagation delay through the delay stage is adjusted by controlling the drive currents through transistors M1 and M2 by varying the control voltage VC and the drive currents through transistors M10 and M9 by varying the control voltage VR. Transistors M3, M7 and M4, MS act as simple inverters and have minimal effect on the propagation delay through the delay stage. Transistors M14 and M13 are connected as capacitors between VC and the power supply, and VR and ground respectively. In concert with the equivalent transistors in all other delay stages in all voltage controlled delay lines, these capacitor-connected transistors act as integrating capacitors on VC and VR respectively. The buffer amplifier consisting of transistors M17 and M18 is coupled to the output of the delay stage on node OUT and drives the tap selection multiplexing transmission gate including transistors M29 and M30. An identical buffer amplifier including transistors M17 and M18 is coupled to intermediate node D1 in order to match the load capacitance to that on node OUT. By matching the drive currents and load capacitance on nodes D1 and OUT, any variation between the propagation delay for rising signals and falling signals are compensated for through the individual delay stages. Two stages of inversion are also required in order for the output at the tap to be in phase with the input to the stage.

The selection circuitry for turning the multiplexing transmission gate on includes a four-input AND gate that is made of the NAND gate including transistors M19-M23, M25-M27, and inverter M38-M39. Each individual delay stage in the slave delay lines and the extension delay line receives a unique combination of tap and length selection signals, respectively, and their complementary signals on their respective busses as is shown in FIG. 1. Referring back to FIG. 2, the four-input NAND gate within one, and only one, of the delay stages in each delay line has all of the signals TSO-TS3 at a logic high state causing the signal on node TAPEN to go high, and passing the signal on OUT of that stage to the “MUXED TAP OUTPUT” line as shown in FIG. 1. In the case of the length control signals, the most significant bit is tied high in this example since only a 1:8 selection is required.

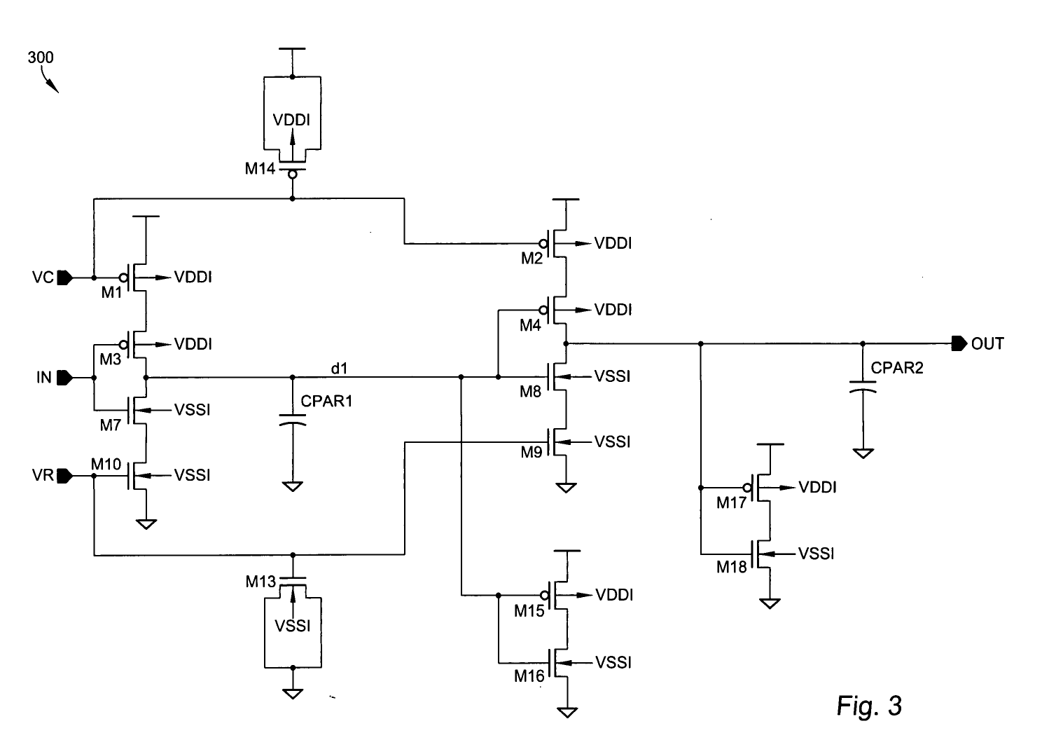

Referring now to FIG. 3, a transistor-level schematic is shown of a delay stage 300, designated “VDELM” in FIG. 1, that is used to implement the fixed-length voltage-controlled delay line. The actual delay elements and the respective load capacitances on nodes D1 and OUT are the same as those in the VDELS delay stage 200 described above. Thus the delay through the stage as a function of control voltages VR and VC is substantially identical for the two types of delay stages shown in FIGS. 2 and 3. However, the outputs of the individual stages in the delay stage 300 of FIG. 3 do not need to be brought out in the fixed delay line so none of the tap selection circuitry is included.

FIG. 4 is a graph 400 showing the possible slave delays for all combinations of the total number of stages in the master delay line with a fixed delay of fifteen stages and the extension delay variable between one and eight stages and the number of stages in the slave between the input and the selected tap variable between one and sixteen stages. The delays have been sorted in ascending order and any duplications of delay eliminated. Thus the label of the Y-axis is “Delay in Nanoseconds”. The “Setting Combination Sequence Number” along the X-axis has no inherent significance, since the combinations are simply numbered sequentially in the order of increasing delay. The clock period used in FIG. 4 is four nanoseconds and the buffer delay used is equal to 0.1 nanoseconds.

FIG. 5 is a graph 502 showing the difference in delay between two successive delays of the graph 400 shown in FIG. 4 and a reference resolution 500 provided by a fixed 23-stage master delay line. These differences represent the resolution that can be achieved around any specific delay target. The resolutions are compared to the fixed resolution that could be achieved if the master delay line was fixed at 23 stages as in the prior art. Since the maximum slave delay possible with 23 stages in the master delay line and 16 stages in the slave is (16/23)*3.9 nanoseconds, the comparison is meaningless beyond this point and no further prior art resolution 500 is therefore shown in FIG. 5. This demonstrates a further benefit of the present invention. The resolution is improved by at least a factor of two except for a single case where the improvement is a factor of 1.8 over the range that a comparison is meaningful. The X-axis label is the same as in FIG. 4, and Y-axis label in FIG. 5 is “Change in Nanoseconds”.

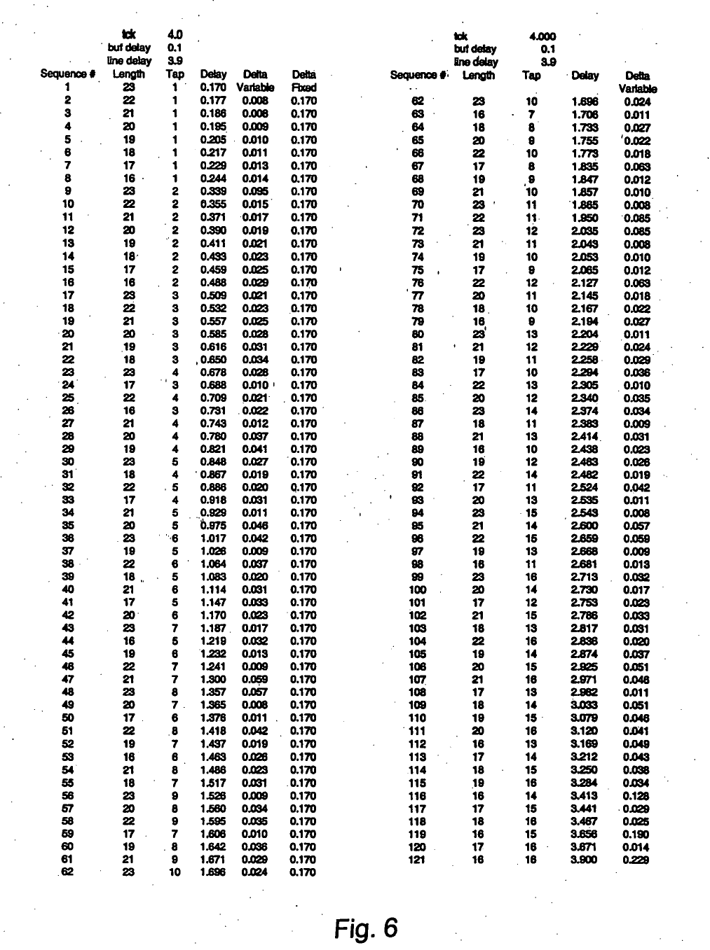

The table of FIG. 6 shows the actual length and tap combinations with the associated delays and differences between successive delays. The data in FIG. 6 was used to prepare the graphs of FIGS. 4 and 5.

While the invention has been particularly shown and described with reference to an embodiment thereof, it will be understood by those skilled in the art that various other changes in the form and details may be made without departing from the spirit and scope of the invention. It should be understood that this description has been made by way of example, and that the invention is defined by the scope of the following claims.

We claim:

1. A method of improving the timing resolution of a delay line comprising:
operating a master voltage-controlled delay line including a selectable number of unit delay stages in a delay locked loop to establish unit delays and associated control voltages; and
using the control voltages to establish delays through a slave voltage-controlled delay line slaved to the master voltage-controlled delay line also having a selectable number of unit delay stages in the slave delay path.

2. The method of claim 1 further comprising using an additional voltage-controlled slave delay line slaved to the master voltage-controlled delay line.

3. The method of claim 1 further comprising using a plurality of additional slave voltage-controlled delay lines slaved to the master voltage-controlled delay line.

4. The method of claim 1 further comprising using substantially identical unit delay stages in the slave voltage-controlled delay line and in the master voltage-controlled delay line.

5. The method according to claim 1 further comprising adjusting the length of the master voltage-controlled delay line.

6. The method according to claim 1 further comprising adjusting the number of unit delays in the slave voltage-controlled delay line.

7. The method according to claim 1 further comprising electrically adjusting both the length of the master voltage-controlled delay line and the number of unit delays in the slave voltage-controlled delay line.

8. The method according to claim 1 further comprising dividing the master voltage-controlled delay line into a fixed length portion and a selectable variable length portion.

9. The method according to claim 8 further comprising using fifteen unit delay stages in the fixed length portion.

10. The method according to claim 8 further comprising using a maximum of eight delay stages in the variable length portion.

11. A delay line circuit comprising:
a master voltage-controlled delay line including a selectable number of unit delay stages in a delay locked loop to establish unit delays and associated control voltages; and
a slave voltage-controlled delay line slaved to the master voltage-controlled delay line also having a selectable number of unit delay stages in the slave delay path.

12. The delay line circuit of claim 11 further comprising a control block for providing control voltages to both the master voltage-controlled delay line and the slave voltage-controlled delay line.

13. The delay line circuit of claim 11 further comprising an additional voltage-controlled slave delay line slaved to the master voltage-controlled delay line.

14. The delay line circuit of claim 11 further comprising a plurality of additional slave voltage-controlled delay lines slaved to the master voltage-controlled delay line.

15. The delay line circuit of claim 11 further comprising substantially identical unit delay stages in the slave voltage-controlled delay line and in the master voltage-controlled delay line.

16. The delay line circuit of claim 11 further comprising circuitry for electrically adjusting both the length of the master voltage-controlled delay line and the number of unit delays in the slave voltage-controlled delay line.

17. The delay line circuit of claim 11 wherein the master voltage-controlled delay line further comprises a fixed length portion and a selectable variable length portion.

18. The delay line circuit of claim 17 wherein the fixed length portion comprises fifteen unit delay stages and wherein the variable length portion comprises a maximum of eight delay stages.

19. The delay line circuit of claim 11 wherein the master voltage-controlled delay line further comprises multiplexing circuitry for receiving a length control signal.

20. The delay line circuit of claim 11 wherein the slave voltage-controlled delay line further comprises multiplexing circuitry having an input for receiving a select signal and an output for providing an output tap signal.
